(19) United States
(12) Patent Application Publication
(10) Pub. No.: US 2026/0171992 A1
(43) Pub. Date: Jun. 18, 2026

(54) POWER SUPPLY SWITCHING DEVICE AND POWER AMPLIFIER MODULE

(71) Applicant: Murata Manufacturing Co., Ltd., Nagaokakyo-shi, (JP)

(72) Inventor: Wataru TAKAHASHI, Nagaokakyo-shi, (JP)

(21) Appl. No.: 19/416,635

(22) Filed: Dec. 11, 2025

(30) Foreign Application Priority Data
Dec. 16, 2024 (JP) 2024-220315

(51) Int. Cl. H03F 3/72; H03F 3/24

(52) U.S. Cl. CPC H03F 3/72; H03F 3/245; H03F 2200/451; H03F 2203/7227

(57) ABSTRACT

A power supply switching device includes a switch circuit including a first switching transistor including a first power supply end that is electrically connected to a first power supply that supplies a first voltage, a first amplifier end that is electrically connected to a power amplifier that amplifies and outputs a high frequency signal, and a first control end for controlling electric conduction between the first power supply end and the first amplifier end, a second switching transistor including a second power supply end that is electrically connected to a second power supply that supplies a second voltage different from the first voltage, a second amplifier end that is electrically connected to the power amplifier, and a second control end for controlling electric conduction between the second power supply end and the second amplifier end, and a shunt unit including at least one shunt transistor.

### CROSS REFERENCE TO RELATED APPLICATION

This application claims priority from Japanese Patent Application No. 2024-220315, filed on Dec. 16, 2024. The content of these applications are incorporated herein by reference in its entirety.

### BACKGROUND OF THE DISCLOSURE

### 1. Field of the Disclosure

The present disclosure relates to a power supply switching device and a power amplifier module.

### 2. Description of the Related Art

Switch circuits provided in wireless communication apparatuses supporting multiple bands have been known (for example, see Japanese Unexamined Patent Application Publication No. 2020-150510).

### BRIEF SUMMARY OF THE DISCLOSURE

A switch circuit described in Japanese Unexamined Patent Application Publication No. 2020-150510 is a circuit that switches between paths for high frequency signals.

In known wireless communication apparatuses that implement high-speed (nS level) switching between power supplies of different voltages by using, for example, Evolved-Universal Terrestrial Radio Access-New Radio Dual Connectivity (ENDC), a switch capable of rapid switching between power supplies is provided. For example, a known power amplifier module 200 will be described with reference to FIG. 7. FIG. 7 is a diagram illustrating an example of a configuration of the known power amplifier module 200.

As illustrated in FIG. 7, the power amplifier module 200 includes a power amplifier 210 that amplifies an input signal RFin and outputs an output signal RFout and a switch 220 that switches between power supplies Vdd1 and Vdd2 of different voltages. In the power amplifier module 200, a capacitor and a parasitic capacitor are present in, for example, power supply wires between the power amplifier 210 and the power supplies Vdd1 and Vdd2. Electric charge is charged into these capacitors.

In the power amplifier module 200, when an operation for switching the power supply Vdd1 which is connected to the power amplifier 210 with the power supply Vdd2 is performed, electric charge in a capacitor flows as a spike current towards the power supply. This spike current causes breaking of the power supply.

The switch circuit described in Japanese Unexamined Patent Application Publication No. 2020-150510 is not usable as a switch for switching between power supplies for a power amplifier circuit. Even if the configuration of the switch circuit described in Japanese Unexamined Patent Application Publication No. 2020-150510 is applicable to switching between power supplies for a power amplifier circuit, switching between power supplies cannot be performed rapidly with the configuration of the switch circuit described in Japanese Unexamined Patent Application Publication No. 2020-150510.

This is because although control signals for rapidly switching individual switches in the switch circuit need to be sequentially inputted from an external apparatus in order to apply the switch circuit described in Japanese Unexamined Patent Application Publication No. 2020-150510 to a power supply switching operation for a power amplifier module, it is difficult, from the viewpoint of designing, to sequentially input such control signals from an external apparatus 3000 at high speed.

That is, the switch circuit described in Japanese Unexamined Patent Application Publication No. 2020-150510 is not usable as a switch circuit for switching between power supplies for the power amplifier module 200, and generation of a spike current at the time of switching of a switch in the power amplifier module 200 cannot be prevented properly.

Accordingly, it is a possible benefit of the present disclosure to prevent generation of a spike current at the time of switching between power supplies.

A power supply switching device according to an aspect of the present disclosure includes a switch circuit including a first switching transistor including a first power supply end that is electrically connected to a first power supply that supplies a first voltage, a first amplifier end that is electrically connected to a power amplifier that amplifies and outputs a high frequency signal, and a first control end for controlling electric conduction between the first power supply end and the first amplifier end, a second switching transistor including a second power supply end that is electrically connected to a second power supply that supplies a second voltage different from the first voltage, a second amplifier end that is electrically connected to the power amplifier, and a second control end for controlling electric conduction between the second power supply end and the second amplifier end, and a shunt unit including at least one shunt transistor, the at least one shunt transistor including a connection end that is electrically connected at least one of between the first amplifier end and the power amplifier and between the second amplifier end and the power amplifier, a ground end that is electrically connected to a ground, and a shunt control end for controlling electric conduction between the connection end and the ground end; and a control circuit that controls a voltage or a current at each of the first control end, the second control end, and the shunt control end. The control circuit stops supply of a control voltage or a control current to the first control end, on the basis of a control signal indicating switching between a first connection state in which the first voltage is able to be supplied from the first power supply through the first switching transistor to the power amplifier and a second connection state in which the second voltage is able to be supplied from the second power supply through the second switching transistor to the power amplifier, so that a non-conducting state is established between the first power supply end and the first amplifier end. When the voltage or the current at the first control end has decreased to a first threshold voltage or a first threshold current where the non-conducting state is established between the first power supply end and the first amplifier end, the control circuit supplies the control voltage or the control current to the shunt control end so that a conducting state is established between the connection end and the ground end. After the conducting state is established between the connection end and the ground end, when the voltage or the current at the shunt control end has increased to a setting voltage or a setting current, the control circuit stops the control voltage or the control current to be supplied to the shunt control end so that the non-conducting state is established between the connection end and the ground end. When the voltage or the current at the shunt control end has decreased to a second threshold voltage or a second threshold current, the control circuit supplies the control voltage or the control current to be supplied to the second control end so that the second connection state is entered.

A power amplifier module according to an aspect of the present disclosure includes the power supply switching device described above, and the power amplifier.

According to the present disclosure, generation of a spike current at the time of switching between power supplies can be prevented.

### BRIEF DESCRIPTION OF THE SEVERAL VIEWS OF THE DRAWINGS

FIG. 1 is a diagram illustrating an example of configurations of various circuits relating to a power amplifier module according to an embodiment of the present disclosure;

FIG. 2 is a diagram illustrating an example of a configuration of a power supply switching device;

Each of FIGS. 3A, 3B and 3C is a graph indicating an operation of the power supply switching device;

FIG. 4 includes diagrams illustrating operations of switching transistors and a shunt unit in the power supply switching device;

FIG. 5 is a diagram illustrating an example of a configuration of a power supply switching device according to a modification;

FIGS. 6A, 6B and 6C include diagrams illustrating operations of switching transistors, shunt transistors, and adjustment transistors in the power supply switching device according to the modification; and

FIG. 7 is a diagram illustrating an example of a configuration of a known power amplifier module.

### DETAILED DESCRIPTION OF THE DISCLOSURE

Hereinafter, embodiments of the present disclosure will be described with reference to the drawings. Circuit elements with the same signs represent the same circuit elements and repetitive explanation will be omitted.

### Configuration of Power Amplifier Module 100

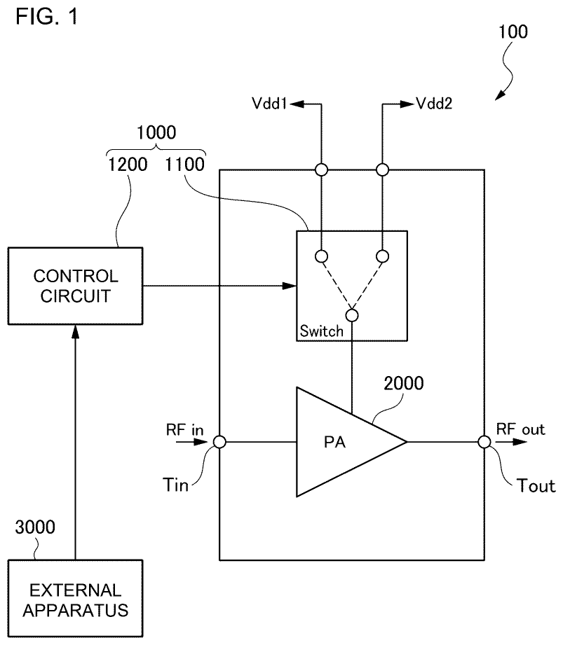

Overview of a configuration of a power amplifier module 100 will be described with reference to FIG. 1. FIG. 1 is a diagram illustrating an example of configurations of various circuits relating to the power amplifier module 100 according to an embodiment of the present disclosure.

The power amplifier module 100 is mounted on, for example, a mobile communication device such as a mobile phone and is used to amplify power of a radio-frequency (RF) signal to be transmitted to a base station. The power amplifier module 100 amplifies power of signals based on, for example, communication standards such as the second generation mobile communication system (2G), the third generation mobile communication system (3G), the fourth generation mobile communication system (4G), the fifth generation mobile communication system (5G), Long Term Evolution-Frequency Division Duplex (LTE-FDD), Long Term Evolution-Time Division Duplex (LTE-TDD), LTE-Advanced, LTE-Advanced Pro, and the sixth generation mobile communication system (6G). Furthermore, for example, the frequency of RF signals ranges from about several hundred MHz to about several ten GHz. Communication standards for signals amplified by the power amplifier module 100 are not limited to the examples mentioned above.

As illustrated in FIG. 1, the power amplifier module 100 includes, for example, a power supply switching device 1000 and a power amplifier 2000.

The power supply switching device 1000 is a switch device that is provided in series between power supplies and the power amplifier 2000. The power supply switching device 1000 switches between power supplies for the power amplifier 2000. The power supply switching device 1000 is connected to each of power supplies of different voltages. Hereinafter, for example, the power supply switching device 1000 is electrically connected to a first power supply Vdd1 that supplies a first voltage (for example, 5 V) and a second power supply Vdd2 that supplies a second voltage (for example, 0.5 V) that is different from the first voltage.

The power supply switching device 1000 includes transistors. The transistors are field effect transistors, bipolar transistors, or the like. Hereinafter, it is assumed, for example, that the power supply switching device 1000 includes field effect transistors.

In the description provided below, in the case where the transistors included in the power supply switching device 1000 are bipolar transistors, “voltage” shall be replaced with “current,” “drain” shall be replaced with “collector,” “source” shall be replaced with “emitter,” and “gate” shall be replaced with “base.”

Regarding each of the transistors included in the power supply switching device 1000, gate voltage is controlled based on a control voltage supplied from a control circuit 1200, which will be described later, to the gate thereof. Thus, the power supply switching device 1000 switches the connection state of the first power supply Vdd1 and the second power supply Vdd2.

The first power supply Vdd1 is a power supply that supplies a predetermined voltage (for example, 5 V) to the power amplifier 2000 that amplifies and outputs a high-frequency radio-frequency signal. The second power supply Vdd2 is a power supply that supplies a voltage (for example, 0.5 V) that is different from the voltage of the first power supply Vdd1 to the power amplifier 2000.

Hereinafter, a state in which the power amplifier 2000 is electrically connected to the first power supply Vdd1 will be referred to as a “first connection state,” and a state in which the power amplifier 2000 is electrically connected to the second power supply Vdd2 will be referred to as a “second connection state.”

The power supply switching device 1000 has a configuration that prevents generation of a spike current at the time of switching from the first connection state to the second connection state. This configuration will be described later.

Accordingly, in a wireless communication apparatus that requires high-speed (nS level) switching between power supplies of different voltages by using, for example, ENDC, the power amplifier module 100 can properly switch between power supplies without generating a spike current.

Although generation of a spike current can be prevented by, as a method for preventing generation of a spike current, providing on a power supply side a capacitor with a capacitance that is about 100 times the capacitance of a capacitor causing generation of a spike current, such a capacitor with a large capacitance cannot be provided on the power supply side when the driving capacity of the power supply for the power amplifier module is taken into consideration.

The power amplifier 2000 is an amplifier that amplifies an input high-frequency radio-frequency (RF) signal (hereinafter, referred to as an “input signal RFin”) and outputs the amplified signal (hereinafter, referred to as an “output signal RFout”). The frequency of the input signal RFin is, for example, about several GHz. Although not particularly limited, the power amplifier 2000 includes, for example, bipolar transistors such as heterojunction bipolar transistors (HBTs) or transistors such as field effect transistors (metal-oxide-semiconductor field effect transistors (MOSFETs)).

### Power Supply Switching Device 1000 Configuration

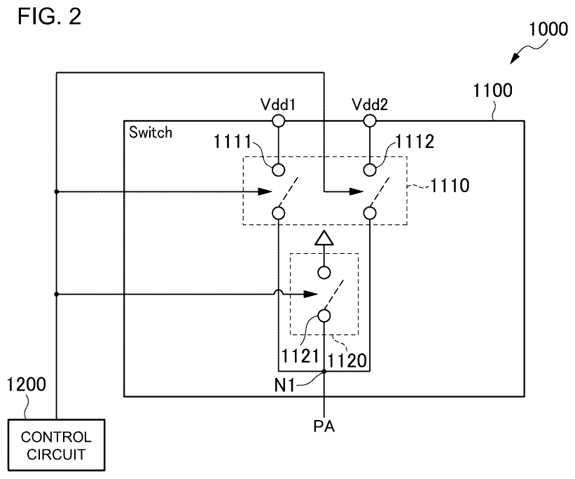

A configuration of the power supply switching device 1000 will be described with reference to FIG. 2. FIG. 2 is a diagram illustrating an example of the configuration of the power supply switching device 1000. As illustrated in FIG. 2, the power supply switching device 1000 includes a switch circuit 1100 and the control circuit 1200.

The switch circuit 1100 is a circuit that switches between the first connection state and the second connection state. A configuration of the switch circuit 1100 will be described with reference to FIG. 2. FIG. 2 is a diagram illustrating an example of the configuration of the switch circuit 1100.

As illustrated in FIG. 2, the switch circuit 1100 includes a switching unit 1110 and a shunt unit 1120.

The switching unit 1110 is a circuit capable of switching between the first power supply Vdd1 and the second power supply Vdd2. The switching unit 1110 includes an end portion that is electrically connected to the first power supply Vdd1 and the second power supply Vdd2 in such a manner that switching is possible between the first power supply Vdd1 and the second power supply Vdd2 and an end portion that is electrically connected to the power amplifier 2000. The switching unit 1110 includes, for example, a switching transistor 1111 and a switching transistor 1112.

The switching transistor 1111 includes a first power supply end, a first amplifier end, and a first control end. The first power supply end is an end portion electrically connected to the first power supply and is, for example, a source. The first amplifier end is an end portion electrically connected to the power amplifier 2000 and is, for example, a drain. The first control end is an end portion to which a control voltage for controlling electric conduction between the first power supply end and the first amplifier end is supplied and is, for example, a gate. Hereinafter, for convenience of explanation, the first power supply end will be referred to as a “source,” the first amplifier end will be referred to as a “drain,” and the first control end will be referred to as a “gate.”

That is, for example, the source of the switching transistor 1111 is electrically connected to the first power supply Vdd1, the drain of the switching transistor 1111 is electrically connected to the power amplifier 2000, and the gate of the switching transistor 1111 is electrically connected to the control circuit 1200.

Furthermore, hereinafter, a connection point between the drain of the switching transistor 1111 (first amplifier end) and the power amplifier 2000 will be referred to as a “connection point N1.” The shunt unit 1120, which will be described later, is electrically connected to the connection point N1.

The switching transistor 1112 includes a second power supply end, a second amplifier end, and a second control end. The second power supply end is an end portion electrically connected to the second power supply and is, for example, a source. The second amplifier end is an end portion electrically connected to the power amplifier 2000 and is, for example, a drain. The second control end is an end portion to which a control voltage for controlling electric conduction between the second power supply end and the second amplifier end is supplied and is, for example, a gate. Hereinafter, for convenience of explanation, the second power supply end will be referred to as a “source,” the second amplifier end will be referred to as a “drain,” and the second control end will be referred to as a “gate.”

That is, for example, the source of the switching transistor 1112 is electrically connected to the second power supply Vdd2, the drain of the switching transistor 1112 is electrically connected to the power amplifier 2000, and the gate of the switching transistor 1112 is electrically connected to the control circuit 1200. The drain of the switching transistor 1112 is electrically connected to the power amplifier 2000 through the connection point N1.

The shunt unit 1120 is a circuit for eliminating electric charge in a capacitor in the power amplifier module 100. The shunt unit 1120 includes at least one shunt transistor 1121.

The shunt transistor 1121 includes a connection end, a ground end, and a shunt control end. The connection end is an end portion electrically connected to the connection point N1 and is, for example, a source. The ground end is an end portion electrically connected to the ground and is, for example, a drain. The shunt control end is an end portion electrically connected to the control circuit 1200 and is, for example, a gate to which a control voltage for controlling electric conduction between the connection end and the ground end is supplied. Hereinafter, for convenience of explanation, the connection end will be referred to as a “source,” the ground end will be referred to as a “drain,” and the shunt control end will be referred to as a “gate.”

That is, for example, the source of the shunt transistor 1121 is electrically connected to the connection point N1, the drain of the shunt transistor 1121 is electrically connected to the ground, and the gate of the shunt transistor 1121 is electrically connected to the control circuit 1200.

The control circuit 1200 is a circuit that controls an operation of a transistor included in the power supply switching device 1000 by supplying or stopping supply of a control voltage for controlling the gate voltage of the transistor. A control signal from the external apparatus 3000 (for example, an interface supporting Mobile Industry Processor Interface (MIPI)) is inputted to the control circuit 1200.

The control signal is, for example, a signal indicating switching the switching unit 1110, from the first connection state in which a voltage can be supplied from the first power supply Vdd1 to the power amplifier 2000 to the second connection state in which a voltage can be supplied from the second power supply Vdd2 to the power amplifier 2000. Furthermore, the control signal is, for example, a signal indicating switching the switching unit 1110, from the second connection state in which a voltage can be supplied from the second power supply Vdd2 to the power amplifier 2000 to the first connection state in which a voltage can be supplied from the first power supply Vdd1 to the power amplifier 2000.

Furthermore, a setting signal from the external apparatus 3000 for setting a setting voltage Vset regarding timing for switching the shunt transistor 1121 of the shunt unit 1120, from a conducting state to a non-conducting state, is inputted to the control circuit 1200. The control circuit 1200 controls the gate voltage of the shunt transistor 1121 on the basis of the setting signal. Thus, since a user is able to set an operation of the shunt unit 1120 in a desired manner on the basis of the size of electric charge in a capacitor in the power amplifier module 100, the power supply switching device 1000 can properly prevent generation of a spike current.

When acquiring a control signal, the control circuit 1200 automatically performs sequential control of the gate voltages of the switching transistors 1111 and 1112 and the shunt transistor 1121 on the basis of predetermined conditions. For example, the control circuit 1200 includes a comparator circuit that compares the gate voltages of the switching transistors 1111 and 1112 and the shunt transistor 1121 with threshold voltages.

### Operation

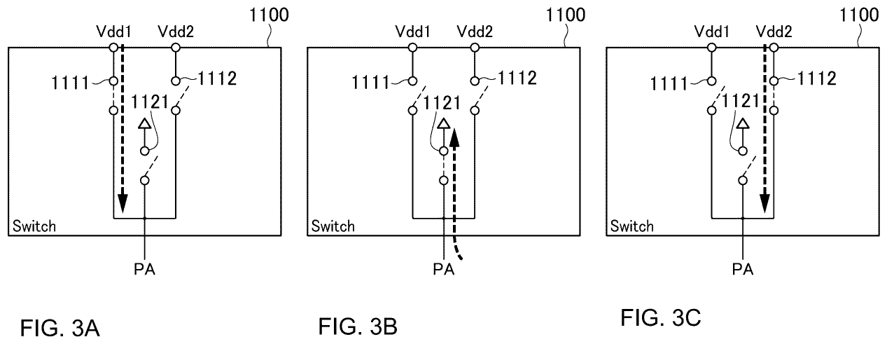

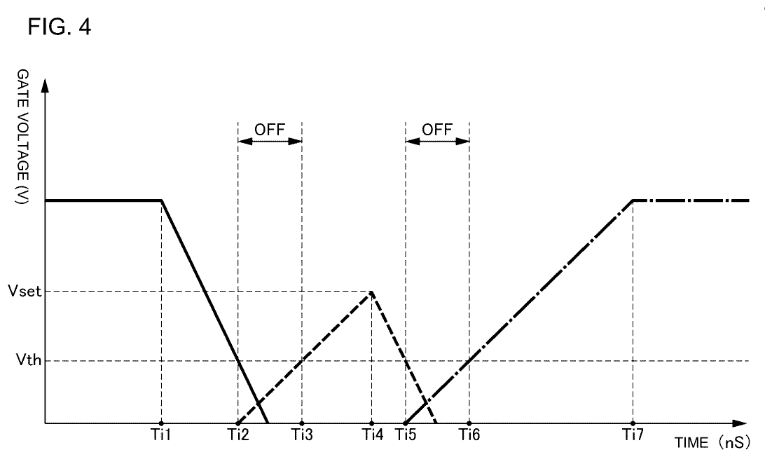

An operation of the power supply switching device 1000 will be described with reference to FIGS. 3A, 3B, 3C and 4.

FIGS. 3A, 3B and 3C include diagrams illustrating operations of the switching transistors 1111 and 1112 and the shunt transistor 1121 in the power supply switching device 1000. In FIG. 3A, a direction of a current flowing from the first power supply Vdd1 to the power amplifier 2000 is indicated by a broken-line arrow. In FIG. 3B, a flow of charged electric charge is indicated by a broken-line arrow. In FIG. 3C, a direction of a current supplied from the first power supply Vdd1 to the power amplifier 2000 is indicated by a broken-line arrow.

FIG. 4 is a graph indicating an operation of the power supply switching device 1000. In FIG. 4, gate voltages of the switching transistors 1111 and 1112 and the shunt transistor 1121 are indicated on the vertical axis, and time (nS) is indicated on the horizontal axis. Furthermore, in FIG. 4, the gate voltage of the switching transistor 1111 is indicated by a solid line, the gate voltage of the shunt transistor 1121 is indicated by a broken line, and the gate voltage of the switching transistor 1112 is indicated by a one-dotted chain line.

Hereinafter, a state in which electric conduction is established between the drain and source of a transistor will be referred to as a “conducting state,” and a state in which electric conduction is not established between the drain and source of a transistor will be referred to as a “non-conducting state.”

As illustrated in FIG. 3A, the control circuit 1200 controls supply and stop of supply of a control voltage to the gate of each of the transistors so that the switching transistor 1111 enters the conducting state, the switching transistor 1112 enters the non-conducting state, and the shunt transistor 1121 enters the non-conducting state. At this time, the power supply switching device 1000 is in the first connection state. In the case where the gate voltage of the switching transistor 1111 is higher than a threshold voltage Vth (for example, 0.7 V), the switching transistor 1111 is in the conducting state.

At time Ti1 indicated in FIG. 4, a control signal is inputted from the external apparatus 3000 to the control circuit 1200. The control circuit 1200 controls the control voltage to be supplied to the gate of the switching transistor 1111 so that the switching transistor 1111 is switched to the non-conducting state. Specifically, the control circuit 1200 performs an operation for stopping supply of the control voltage to the gate of the switching transistor 1111 so that the gate voltage of the switching transistor 1111 keeps decreasing during a period from the time Ti1 to time Ti2 in FIG. 4.

At the time Ti2 indicated in FIG. 4, the control circuit 1200 determines that the gate voltage of the switching transistor 1111 has decreased to the threshold voltage Vth. That is, the control circuit 1200 determines that the switching transistor 1111 has entered the non-conducting state. At this time, the control circuit 1200 controls the control voltage to be supplied to the gate of the shunt transistor 1121 so that the shunt transistor 1121 is switched to the conducting state. Specifically, the control circuit 1200 supplies the control voltage to the gate of the shunt transistor 1121 so that the gate voltage of the shunt transistor 1121 keeps increasing during a period from the time Ti2 to time Ti4 in FIG. 4.

When the gate voltage of the shunt transistor 1121 exceeds the threshold voltage Vth at time Ti3 indicated in FIG. 4, the shunt transistor 1121 enters the conducting state, as illustrated in FIG. 3B.

Next, at the time Ti4 indicated in FIG. 4, the control circuit 1200 determines that the gate voltage of the shunt transistor 1121 has increased to the setting voltage Vset. At this time, the control circuit 1200 controls the control voltage to be supplied to the gate of the shunt transistor 1121 so that the shunt transistor 1121 enters the non-conducting state. Specifically, the control circuit 1200 performs an operation for stopping supply of the control voltage to the gate of the shunt transistor 1121 so that the gate voltage of the shunt transistor 1121 starts to decrease at the time Ti4 in FIG. 4.

Next, at time Ti5 indicated in FIG. 4, the control circuit 1200 determines that the gate voltage of the shunt transistor 1121 has decreased to the threshold voltage Vth. At this time, the control circuit 1200 controls the control voltage to be supplied to the gate of the switching transistor 1112 so that the switching transistor 1112 is switched to the conducting state. Specifically, the control circuit 1200 supplies the control voltage to the gate of the switching transistor 1112 so that the gate voltage of the switching transistor 1112 keeps increasing during a period from the time Ti5 to time Ti7 in FIG. 4.

That is, during a period from the time Ti3 to the time Ti5, in the power supply switching device 1000, the power amplifier 2000 is not electrically connected to the first power supply Vdd1 or the second power supply Vdd2 and the power amplifier 2000 is electrically connected to the ground with the shunt transistor 1121 interposed therebetween. Thus, the power supply switching device 1000 can eliminate electric charge in a capacitor, which causes generation of a spike current.

Furthermore, during the period from the time Ti3 to the time Ti5, since the setting voltage Vset is set based on a setting signal, the power supply switching device 1000 can adjust the time for properly eliminating electric charge in a capacitor in the power amplifier module 100. That is, the power supply switching device 1000 can easily adjust the time for eliminating electric charge in accordance with a setting operation by a user for the external apparatus 3000 on the basis of the size of a capacitor included in the power amplifier module 100.

Furthermore, during a period from the time Ti2 to the time Ti3 and a period from the time Ti5 to the time Ti6, the switching transistors 1111 and 1112 and the shunt transistor 1121 are in the non-conducting state (“OFF” in FIG. 4). Thus, a situation where the power amplifier 2000 is short-circuited to the ground can be reliably prevented.

Next, when the gate voltage of the switching transistor 1112 exceeds the threshold voltage Vth at the time Ti6 indicated in FIG. 4, the conducting state is established between the drain and source of the switching transistor 1112.

That is, in this case, as illustrated in FIG. 3C, the control circuit 1200 controls the control voltage to be supplied to the gate of each of the transistors so that the non-conducting state is established between the drain and source of the switching transistor 1111, the conducting state is established between the drain and source of the switching transistor 1112, and the non-conducting state is established between the drain and source of the shunt transistor 1121. At this time, the power supply switching device 1000 is in the second connection state.

### Power Supply Switching Device 1000a According to Modification

### Configuration

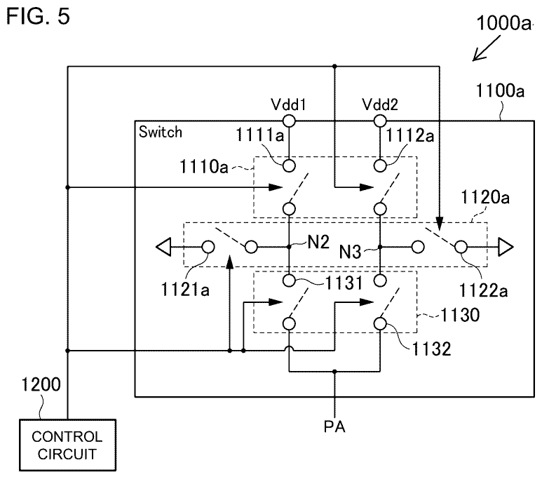

A configuration of a power supply switching device 1000a according to a modification will be described with reference to FIG. 5. FIG. 5 is a diagram illustrating an example of the configuration of the power supply switching device 1000a according to the modification. Only features different from the power supply switching device 1000 will be described below. Unless otherwise stated, the power supply switching device 1000a has the same configuration as that of the power supply switching device 1000.

As illustrated in FIG. 5, the power supply switching device 1000a includes a switch circuit 1100a and the control circuit 1200.

As illustrated in FIG. 2, the switch circuit 1100a includes a switching unit 1110a, a shunt unit 1120a, and a path adjusting unit 1130.

The switching unit 1110a includes, for example, a switching transistor 1111a and a switching transistor 1112a.

A source of the switching transistor 1111a (first power supply end) is electrically connected to the first power supply, a drain of the switching transistor 1111a (first amplifier end) is electrically connected to a first adjustment power supply end of an adjustment transistor 1131, and a control voltage for controlling electric conduction between the first power supply end and the first amplifier end is supplied to a gate of the switching transistor 1111a (first control end). Hereinafter, a connection point between the drain of the switching transistor 1111a and the first adjustment power supply end of the adjustment transistor 1131 will be referred to as a “connection point N2.” A shunt transistor 1121a, which will be described later, is electrically connected to the connection point N2.

A source of the switching transistor 1112a (second power supply end) is electrically connected to the second power supply, a drain of the switching transistor 1112a (second amplifier end) is electrically connected to a second adjustment power supply end of an adjustment transistor 1132, and a control voltage for controlling electric conduction between the second power supply end and the second amplifier end is supplied to a gate of the switching transistor 1112a (second control end). Hereinafter, a connection point between the drain of the switching transistor 1112a and the second adjustment power supply end of the adjustment transistor 1132 will be referred to as a “connection point N3.” A shunt transistor 1122a, which will be described later, is electrically connected to the connection point N3.

The shunt unit 1120a includes, for example, the shunt transistor 1121a and the shunt transistor 1122a.

The shunt transistor 1121a includes a first connection end, a first ground end, and a first shunt control end. The first connection end is an end portion electrically connected to the connection point N2 and is, for example, a source. The first ground end is an end portion electrically connected to the ground and is, for example, a drain. The first shunt control end is an end portion electrically connected to the control circuit 1200 and is, for example, a gate to which a control voltage for controlling electric conduction between the first connection end and the first ground end is supplied. Hereinafter, for convenience of explanation, the first connection end will be referred to as a “source,” the first ground end will be referred to as a “drain,” and the first shunt control end will be referred to as a “gate.”

The shunt transistor 1122a includes a second connection end, a second ground end, and a second shunt control end. The second connection end is an end portion electrically connected to the connection point N3 and is, for example, a source. The second ground end is an end portion electrically connected to the ground and is, for example, a drain. The second shunt control end is an end portion electrically connected to the control circuit 1200 and is, for example, a gate to which a control voltage for controlling electric conduction between the second connection end and the second ground end is supplied. Hereinafter, for convenience of explanation, the second connection end will be referred to as a “source,” the second ground end will be referred to as a “drain,” and the second shunt control end will be referred to as a “gate.”

The path adjusting unit 1130 is a circuit that adjusts a connection path when switching between the first connection state, the second connection state, and a state in which connection to the ground is established is performed. The path adjusting unit 1130 includes, for example, the adjustment transistor 1131 and the adjustment transistor 1132.

The adjustment transistor 1131 includes a first adjustment power supply end, a first adjustment amplifier end, and a first adjustment control end. The first adjustment power supply end is an end portion electrically connected to the drain of the switching transistor 1111a (first amplifier end) through the connection point N2 and is, for example, a source. The first adjustment amplifier end is an end portion electrically connected to the power amplifier 2000 and is, for example, a drain. The first adjustment control end is an end portion to which a control voltage for controlling electric conduction between the first adjustment power supply end and the first adjustment amplifier end is supplied and is, for example, a gate. Hereinafter, for convenience of explanation, the first adjustment power supply end will be referred to as a “source,” the first adjustment amplifier end will be referred to as a “drain,” and the first adjustment control end will be referred to as a “gate.”

The adjustment transistor 1132 includes a second adjustment power supply end, a second adjustment amplifier end, and a second adjustment control end. The second adjustment power supply end is an end portion electrically connected to the drain of the switching transistor 1112a (second amplifier end) through the connection point N3 and is, for example, a source. The second adjustment amplifier end is an end portion electrically connected to the power amplifier 2000 and is, for example, a drain. The second adjustment control end is an end portion to which a control voltage for controlling electric conduction between the second adjustment power supply end and the second adjustment amplifier end is supplied and is, for example, a gate. Hereinafter, for convenience of explanation, the second adjustment power supply end will be referred to as a “source,” the second adjustment amplifier end will be referred to as a “drain,” and the second adjustment control end will be referred to as a “gate.”

When acquiring a control signal, the control circuit 1200 automatically performs sequential control of the gate voltages of the switching transistors 1111a and 1112a, the shunt transistors 1121a and 1122a, and the adjustment transistors 1131 and 1132 on the basis of predetermined conditions.

### Operation

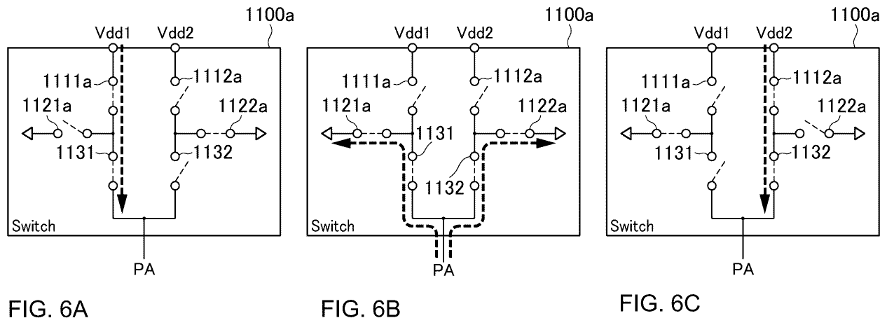

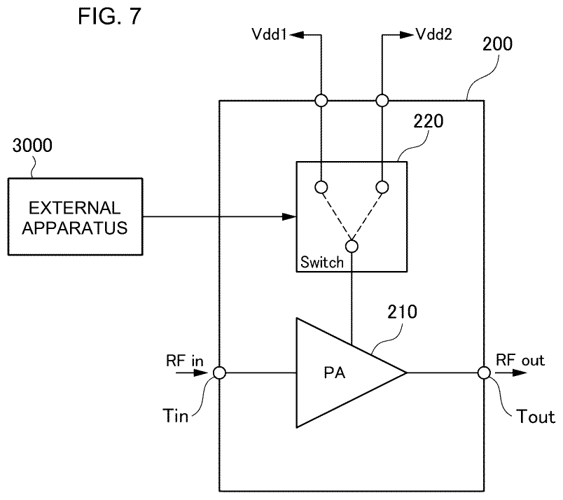

An operation of the power supply switching device 1000a will be described with reference to FIGS. 6A, 6B and 6C. FIGS. 6A, 6B and 6C include diagrams illustrating operations of the switching transistors 1111a and 1112a, the shunt transistors 1121a and 1122a, and the adjustment transistors 1131 and 1132 in the power supply switching device 1000a according to the modification. In FIG. 6A, a direction of a current flowing from the first power supply Vdd1 to the power amplifier 2000 is indicated by a broken-line arrow. In FIG. 6B, a flow of charged electric charge is indicated by a broken-line arrow. In FIG. 6C, a direction of a current supplied from the first power supply Vdd1 to the power amplifier 2000 is indicated by a broken-line arrow.

Since a graph indicating the gate voltages of the transistors is similar to that in FIG. 4, explanation for the graph will be omitted below. In the description provided below, as in FIG. 4, it is assumed that the gate voltages for switching the shunt transistors 1121a and 1122a to the non-conducting state are set to the setting voltage Vset in the control circuit 1200.

Hereinafter, a state in which electric conduction is established between the drain and source of a transistor will be referred to as a “conducting state,” and a state in which electric conduction is not established between the drain and source of a transistor will be referred to as a “non-conducting state.”

As illustrated in FIG. 6A, the control circuit 1200 controls the gate voltages of the transistors so that the switching transistor 1111a enters the conducting state, the switching transistor 1112a enters the non-conducting state, the shunt transistor 1121a enters the non-conducting state, the shunt transistor 1122a enters the conducting state, the adjustment transistor 1131 enters the conducting state, and the adjustment transistor 1132 enters the non-conducting state. At this time, the power supply switching device 1000 is in the first connection state.

Next, a control signal is inputted from the external apparatus 3000 to the control circuit 1200. The control circuit 1200 controls a control voltage to be supplied to the gate of the switching transistor 1111a so that the switching transistor 1111a is switched to the non-conducting state. At this time, the gate voltage of the switching transistor 1111a gradually decreases.

Next, the control circuit 1200 determines that the gate voltage of the switching transistor 1111a has decreased to the threshold voltage Vth. That is, the control circuit 1200 determines that the switching transistor 1111a has entered the non-conducting state. At this time, the control circuit 1200 controls control voltages to be supplied to the gates of the shunt transistor 1121a and the adjustment transistor 1132 so that the shunt transistor 1121a and the adjustment transistor 1132 are each switched to the conducting state. Thus, the gate voltages of the shunt transistor 1121a and the adjustment transistor 1132 gradually increase.

When the gate voltages of the shunt transistor 1121a and the adjustment transistor 1132 have increased to the threshold voltage Vth, the shunt transistor 1121a and the adjustment transistor 1132 each enter the conducting state, as illustrated in FIG. 6B. At this time, the shunt transistor 1122a is in the conducting state.

Next, the control circuit 1200 determines that the gate voltage of the shunt transistor 1121a has increased to the setting voltage Vset. At this time, the control circuit 1200 controls control voltages to be supplied to the gate of the shunt transistor 1122a and the gate of the adjustment transistor 1131 (for example, stops control voltages) so that the shunt transistor 1122a and the adjustment transistor 1131 are each switched to the non-conducting state. Thus, the gate voltages of the shunt transistor 1122a and the adjustment transistor 1131 gradually decrease.

As described above, the control circuit 1200 determines that the gate voltage of the shunt transistor 1121a has increased to the setting voltage Vset. However, the control circuit 1200 does not necessarily perform determination as described above. For example, the control circuit 1200 may determine that at least one of the gate voltage of the shunt transistor 1121a and the gate voltage of the shunt transistor 1122a has increased to the setting voltage Vset.

Next, the control circuit 1200 determines that the gate voltage of the shunt transistor 1122a and the gate voltage of the adjustment transistor 1131 have decreased to the threshold voltage Vth. That is, the control circuit 1200 determines that the power amplifier 2000 and the ground have become electrically disconnected. At this time, the control circuit 1200 controls the gate voltage of the switching transistor 1112a so that the switching transistor 1112a is switched to the conducting state. Thus, the gate voltage of the switching transistor 1112a gradually increases.

That is, in the power supply switching device 1000, the power amplifier 2000 is not electrically connected to the first power supply Vdd1 or the second power supply Vdd2 (in the state illustrated in FIG. 6B) and the power amplifier 2000 is electrically connected to the ground with the shunt transistors 1121a and 1122a interposed therebetween. Thus, the power supply switching device 1000a can eliminate electric charge in a capacitor, which causes generation of a spike current.

Furthermore, since the setting voltage Vset is set based on a setting signal, the power supply switching device 1000a can adjust the time for properly eliminating electric charge in a capacitor in the power amplifier module 100. That is, the power supply switching device 1000a can easily adjust the time for eliminating electric charge in accordance with a setting operation by a user for the external apparatus 3000 on the basis of the size of a capacitance component included in the power amplifier module 100.

Next, when the gate voltage of the switching transistor 1112a has increased to the threshold voltage Vth, the switching transistor 1112a is switched to the conducting state.

That is, in this case, as illustrated in FIG. 6C, the control circuit 1200 controls the gate voltages of the transistors so that the switching transistor 1111a enters the non-conducting state, the switching transistor 1112a enters the conducting state, and the shunt transistor 1122a and the adjustment transistor 1131 each enter the non-conducting state. At this time, the power supply switching device 1000 is in the second connection state.

Thus, compared to the power supply switching device 1000, the power supply switching device 1000a can reliably eliminate electric charge in a capacitor and can properly prevent generation of a spike current.

### Conclusion

<1> The power supply switching device 1000 includes the switch circuit 1100 including the switching transistor 1111 (first switching transistor) including the first power supply end (for example, a source or an emitter) that is electrically connected to the first power supply Vdd1 that supplies the first voltage, the first amplifier end (for example, a drain or a collector) that is electrically connected to the power amplifier 2000 that amplifies and outputs a high frequency signal, and the first control end (for example, a gate or a base) for controlling electric conduction between the first power supply end and the first amplifier end, the switching transistor 1112 (second switching transistor) including the second power supply end (for example, a source or an emitter) that is electrically connected to the second power supply Vdd2 that supplies the second voltage different from the first voltage, the second amplifier end (for example, a drain or a collector) that is electrically connected to the power amplifier 2000, and the second control end (for example, a gate or a base) for controlling electric conduction between the second power supply end and the second amplifier end, and the shunt unit 1120 including at least one shunt transistor, the at least one shunt transistor including the connection end (for example, a source or an emitter) that is electrically connected at least one of between the first amplifier end and the power amplifier 2000 and between the second amplifier end and the power amplifier 2000, the ground end (for example, a drain or a collector) that is electrically connected to the ground, and the shunt control end (for example, a gate or a base) for controlling electric conduction between the connection end and the ground end; and the control circuit 1200 that controls a voltage or a current at each of the first control end, the second control end, and the shunt control end. The control circuit 1200 stops supply of a control voltage or a control current to the first control end, on the basis of a control signal indicating switching between the first connection state in which the first voltage is able to be supplied from the first power supply Vdd1 through the switching transistor 1111 (first switching transistor) to the power amplifier 2000 and the second connection state in which the second voltage is able to be supplied from the second power supply Vdd2 through the switching transistor 1112 (second switching transistor) to the power amplifier 2000, so that the non-conducting state is established between the first power supply end and the first amplifier end. When the voltage or the current at the first control end has decreased to a first threshold voltage or a first threshold current (for example, the threshold voltage Vth) where the non-conducting state is established between the first power supply end and the first amplifier end, the control circuit 1200 supplies the control voltage or the control current to the shunt control end so that the conducting state is established between the connection end and the ground end. After the conducting state is established between the connection end and the ground end, when the voltage or the current at the shunt control end has increased to a setting voltage or a setting current (for example, the setting voltage Vset), the control circuit 1200 stops the control voltage or the control current to be supplied to the shunt control end so that the non-conducting state is established between the connection end and the ground end. When the voltage or the current at the shunt control end has decreased to a second threshold voltage or a second threshold current, the control circuit 1200 supplies the control voltage or the control current to be supplied to the second control end so that the second connection state is entered. Thus, the power amplifier module 100 can properly eliminate electric charge in a capacitor and can prevent generation of a spike current.
<2> Furthermore, in the power supply switching device 1000 according to <1>, the control circuit 1200 has a function capable of adjusting the setting voltage or the setting current on the basis of a setting signal from a predetermined apparatus (for example, an MIPI). Thus, since a user is able to set an operation of the shunt unit 1120 in a desired manner on the basis of the size of electric charge in the capacitor in the power amplifier module 100, the power supply switching device 1000 can properly prevent generation of a spike current.
<3> Furthermore, in the power supply switching device 1000a according to <1> or <2>, the switch circuit 1100a further includes the adjustment transistor 1131 (first adjustment transistor) including the first adjustment power supply end (for example, a source or an emitter) that is electrically connected to the first amplifier end, the first adjustment amplifier end (for example, a drain or a collector) that is electrically connected to the power amplifier 2000, and the first adjustment control end (for example, a gate or a base) for controlling electric conduction between the first adjustment power supply end and the first adjustment amplifier end, and the adjustment transistor 1132 (second adjustment transistor) including the second adjustment power supply end that is electrically connected to the second amplifier end, the second adjustment amplifier end that is electrically connected to the power amplifier 2000, and the second adjustment control end for controlling electric conduction between the second adjustment power supply end and the second adjustment amplifier end. The at least one shunt transistor includes the shunt transistor 1121a (first shunt transistor) and the shunt transistor 1122a (second shunt transistor). The connection end includes the first connection end (for example, a source or an emitter) of the shunt transistor 1121a (first shunt transistor) that is electrically connected between the first amplifier end and the first adjustment amplifier end and the second connection end (for example, a source or an emitter) of the shunt transistor 1122a (second shunt transistor) that is electrically connected between the second amplifier end and the second adjustment amplifier end. The ground end includes the first ground end (for example, a drain or a collector) of the shunt transistor 1121a (first shunt transistor) that is electrically connected to the ground and the second ground end (for example, a drain or a collector) of the shunt transistor 1122a (second shunt transistor) that is electrically connected to the ground. The shunt control end includes the first shunt control end (for example, a gate or a base) of the shunt transistor 1121a (first shunt transistor) for controlling electric conduction between the first connection end and the first ground end and the second shunt control end (for example, a gate or a base) of the shunt transistor 1122a (second shunt transistor) for controlling electric conduction between the second connection end and the second ground end. The control circuit 1200 stops supply of a control voltage or a control current to the first control end, on the basis of the control signal, so that the non-conducting state is established between the first power supply end and the first amplifier end. When the voltage or the current at the first control end has decreased to the first threshold voltage or the first threshold current (for example, the threshold voltage Vth), the control circuit 1200 causes the power amplifier 2000 and the ground to be electrically connected with the shunt transistor 1121a (first shunt transistor) interposed therebetween by supplying the control voltage or the control current to the first shunt control end so that the conducting state is established between the first connection end and the first ground end, and the control circuit 1200 causes the power amplifier 2000 and the ground to be electrically connected with the shunt transistor 1122a (second shunt transistor) interposed therebetween by supplying the control voltage or the control current to the second adjustment control end so that the conducting state is established between the second adjustment power supply end and the second adjustment amplifier end. After the power amplifier 2000 and the ground are electrically connected, when the voltage or the current at at least one of the first shunt control end and the second shunt control end has increased to the setting voltage or the setting current (for example, the setting voltage Vset), the control circuit 1200 stops the control voltage or the control current to be supplied to each of the first adjustment control end and the second shunt control end so that the power amplifier 2000 and the ground are electrically disconnected. When the voltage or the current at the first adjustment control end and the second shunt control end has decreased to the second threshold voltage or the second threshold current (for example, the threshold voltage Vth), the control circuit 1200 supplies the control voltage or the control current to the second control end so that the second connection state is entered. Thus, the power amplifier module 100 can eliminate electric charge in the capacitor more reliably and can prevent generation of a spike current more properly.
<4> Furthermore, the power amplifier module 100 includes the power supply switching device 1000 according to any one of <1> to <3>, and the power amplifier 2000. Thus, the power amplifier module 100 can properly eliminate electric charge in the capacitor and can prevent generation a spike current.

The embodiments described above are intended to facilitate understanding of the present disclosure and are not to be interpreted as limiting the present disclosure. The present disclosure can be modified or improved without departing from the gist of the disclosure, and the present disclosure encompasses equivalents thereof. That is, design changes appropriately added to the embodiments by those skilled in the art are also included in the scope of the present disclosure as long as the design changes include features of the present disclosure. For example, elements included in each of the embodiments and arrangement of the elements are not limited to those illustrated above and can be modified appropriately.

What is claimed is:

1. A power supply switching device comprising:
a switch circuit comprising:
a first switching transistor having a first power supply end that is electrically connected to a first power supply that supplies a first voltage, a first amplifier end that is electrically connected to a power amplifier that amplifies and outputs a high frequency signal, and a first control end configured to control electric conduction between the first power supply end and the first amplifier end,
a second switching transistor having a second power supply end that is electrically connected to a second power supply that supplies a second voltage different from the first voltage, a second amplifier end that is electrically connected to the power amplifier, and a second control end configured to control electric conduction between the second power supply end and the second amplifier end, and
a shunt unit comprising at least one shunt transistor, the at least one shunt transistor having a connection end that is electrically connected between the first amplifier end and the power amplifier or between the second amplifier end and the power amplifier, a ground end that is electrically connected to ground, and a shunt control end configured to control electric conduction between the connection end and the ground end; and
a control circuit configured to control a voltage or a current at each of the first control end, the second control end, and the shunt control end,
wherein the control circuit is configured to stop supply of a control voltage or a control current to the first control end based on a control signal indicating that switching between a first connection state and a second connection state, such that a non-conducting state is established between the first power supply end and the first amplifier end,
wherein in the first connection state, the first voltage is supplied from the first power supply through the first switching transistor to the power amplifier,
wherein in the second connection state, the second voltage is supplied from the second power supply through the second switching transistor to the power amplifier,
wherein when the voltage or the current at the first control end has decreased to a first threshold voltage or a first threshold current and the first power supply end and the first amplifier end are in a non-conducting state, the control circuit is configured to supply the control voltage or the control current to the shunt control end such that a conducting state is established between the connection end and the ground end,
wherein after the conducting state is established between the connection end and the ground end, when the voltage or the current at the shunt control end has increased to a setting voltage or a setting current, the control circuit is configured to stop supply of the control voltage or the control current to the shunt control end such that the non-conducting state is established between the connection end and the ground end, and
wherein when the voltage or the current at the shunt control end has decreased to a second threshold voltage or a second threshold current, the control circuit is configured to supply the control voltage or the control current to the second control end such that the second connection state is entered.

2. The power supply switching device according to claim 1, wherein the control circuit is configured to adjust the setting voltage or the setting current based on a setting signal from a predetermined apparatus.

3. The power supply switching device according to claim 1,
wherein the switch circuit further comprises:
a first adjustment transistor having a first adjustment power supply end that is electrically connected to the first amplifier end, a first adjustment amplifier end that is electrically connected to the power amplifier, and a first adjustment control end configured to control electric conduction between the first adjustment power supply end and the first adjustment amplifier end, and
a second adjustment transistor having a second adjustment power supply end that is electrically connected to the second amplifier end, a second adjustment amplifier end that is electrically connected to the power amplifier, and a second adjustment control end configured to control electric conduction between the second adjustment power supply end and the second adjustment amplifier end,
wherein the at least one shunt transistor comprises:
a first shunt transistor and a second shunt transistor,
the connection end of the at least one shunt transistor including a first connection end of the first shunt transistor that is electrically connected between the first amplifier end and the first adjustment amplifier end, and a second connection end of the second shunt transistor that is electrically connected between the second amplifier end and the second adjustment amplifier end,
the ground end of the at least one shunt transistor including a first ground end of the first shunt transistor that is electrically connected to the ground, and a second ground end of the second shunt transistor that is electrically connected to the ground, and
the shunt control end of the at least one shunt transistor including a first shunt control end of the first shunt transistor configured to control electric conduction between the first connection end and the first ground end, and a second shunt control end of the second shunt transistor configured to control electric conduction between the second connection end and the second ground end,
wherein the control circuit is configured to stop supply of the control voltage or the control current to the first control end based on the control signal, such that the non-conducting state is established between the first power supply end and the first amplifier end,
wherein when the voltage or the current at the first control end has decreased to the first threshold voltage or the first threshold current:
the control circuit is configured to cause the power amplifier and the ground to be electrically connected with the first shunt transistor interposed therebetween by supplying the control voltage or the control current to the first shunt control end such that the conducting state is established between the first connection end and the first ground end, and
the control circuit is configured to cause the power amplifier to be electrically connected to ground with the second shunt transistor interposed therebetween by supplying the control voltage or the control current to the second adjustment control end such that the conducting state is established between the second adjustment power supply end and the second adjustment amplifier end,
wherein after the power amplifier is electrically connected to ground, when the voltage or the current at at least one of the first shunt control end and the second shunt control end has increased to the setting voltage or the setting current, the control circuit is configured to stop supply of the control voltage or the control current to each of the first adjustment control end and the second shunt control end such that the power amplifier and the ground are electrically disconnected, and
wherein when the voltage or the current at the first adjustment control end and the second shunt control end has decreased to the second threshold voltage or the second threshold current, the control circuit is configured to supply the control voltage or the control current to the second control end such that the second connection state is entered.

4. The power supply switching device according to claim 2,
wherein the switch circuit further comprises:
a first adjustment transistor having a first adjustment power supply end that is electrically connected to the first amplifier end, a first adjustment amplifier end that is electrically connected to the power amplifier, and a first adjustment control end configured to control electric conduction between the first adjustment power supply end and the first adjustment amplifier end, and
a second adjustment transistor having a second adjustment power supply end that is electrically connected to the second amplifier end, a second adjustment amplifier end that is electrically connected to the power amplifier, and a second adjustment control end configured to control electric conduction between the second adjustment power supply end and the second adjustment amplifier end,
wherein the at least one shunt transistor comprises:
a first shunt transistor and a second shunt transistor,
the connection end of the at least one shunt transistor including a first connection end of the first shunt transistor that is electrically connected between the first amplifier end and the first adjustment amplifier end, and a second connection end of the second shunt transistor that is electrically connected between the second amplifier end and the second adjustment amplifier end,
the ground end of the at least one shunt transistor including a first ground end of the first shunt transistor that is electrically connected to the ground, and a second ground end of the second shunt transistor that is electrically connected to the ground, and
the shunt control end of the at least one shunt transistor including a first shunt control end of the first shunt transistor configured to control electric conduction between the first connection end and the first ground end, and a second shunt control end of the second shunt transistor configured to control electric conduction between the second connection end and the second ground end,
wherein the control circuit is configured to stop supply of the control voltage or the control current to the first control end based on the control signal, such that the non-conducting state is established between the first power supply end and the first amplifier end,
wherein when the voltage or the current at the first control end has decreased to the first threshold voltage or the first threshold current:
the control circuit is configured to cause the power amplifier and the ground to be electrically connected with the first shunt transistor interposed therebetween by supplying the control voltage or the control current to the first shunt control end such that the conducting state is established between the first connection end and the first ground end, and
the control circuit is configured to cause the power amplifier to be electrically connected to ground with the second shunt transistor interposed therebetween by supplying the control voltage or the control current to the second adjustment control end such that the conducting state is established between the second adjustment power supply end and the second adjustment amplifier end,
wherein after the power amplifier is electrically connected to ground, when the voltage or the current at at least one of the first shunt control end and the second shunt control end has increased to the setting voltage or the setting current, the control circuit is configured to stop supply of the control voltage or the control current to each of the first adjustment control end and the second shunt control end such that the power amplifier and the ground are electrically disconnected, and
wherein when the voltage or the current at the first adjustment control end and the second shunt control end has decreased to the second threshold voltage or the second threshold current, the control circuit is configured to supply the control voltage or the control current to the second control end such that the second connection state is entered.

5. A power amplifier module comprising:
the power supply switching device according to claim 1; and
the power amplifier.

6. A power amplifier module comprising:
the power supply switching device according to claim 2; and
the power amplifier.
